(19) United States
(12) Patent Application Publication
(10) Pub. No.: US 2015/0348988 A1
(43) Pub. Date: Dec. 3, 2015

(54) SEMICONDUCTOR MEMORY ELEMENT AND PRODUCTION METHOD THEREFOR

(71) Applicant: (IUCF-HYU (INDUSTRY-UNIVERSITY COOPERATION FOUNDATION HANYANG UNIVERSITY), Seongdong-gu Seoul (KR)

(72) Inventors: Yun Heub Song, Seongnam-si, Gyeonggi-do (KR); Hyung Jun Yang, Seongdong-gu Seoul (KR)

(21) Appl. No.: 14/760,038

(22) PCT Filed: Jan. 14, 2014
(86) PCT No.: PCT/KR2014/000371

§ 371 Date: Jul. 9, 2015

(30) Foreign Application Priority Data
Jan. 15, 2013 (KR) 10-2013-0004521

(51) Int. Cl. H01L 27/115; H01L 29/788; H01L 21/28

(52) U.S. Cl. CPC H01L 27/11582; H01L 27/11556; H01L 21/28282; H01L 21/28273; H01L 29/7883

(57) ABSTRACT

Provided is a semiconductor memory device including a vertical electrode provided on a substrate and a blocking insulating layer provided on a sidewall of the vertical electrode. A plurality of active patterns are provided spaced apart from the vertical electrode by the blocking insulating layer, and memory patterns are provided between the active patterns.

### CROSS-REFERENCE TO RELATED APPLICATION

This application is entitled to the benefit of and incorporates by reference subject matter disclosed in the International Patent Application No. PCT/KR2014/000371 filed on Jan. 14, 2014 and Korean Patent Application Serial No. 10-2013-0004521 filed Jan. 15, 2013.

### TECHNICAL FIELD

Example embodiments of the inventive concept relate to a semiconductor device and a method of fabricating the same, and in particular, to a semiconductor memory device and a method of fabricating the same.

### BACKGROUND OF THE INVENTION

Highly integrated semiconductor memory devices have been increasingly demanded with the development of electronic industry. The integration density of the semiconductor memory devices is a main factor affecting the cost of the semiconductor memory devices. That is, an increase in the integration density of the semiconductor memory devices allows for a reduction in the cost of the semiconductor memory devices. In the case of typical two-dimensional or planar semiconductor memory devices, since their integration is mainly determined by the area occupied by a unit memory cell, integration is greatly influenced by the level of a fine pattern forming technology. However, the extremely expensive process equipment needed to increase pattern fineness sets a practical limitation on increasing integration for two-dimensional or planar semiconductor devices.

To overcome such a limitation, three-dimensional (3D) semiconductor devices including three-dimensionally-arranged memory cells have been proposed. However, there are significant manufacturing obstacles in achieving low-cost, mass-production of 3D semiconductor devices, particularly in the mass-fabrication of 3D devices that maintain or exceed the operational reliability of their 2D counterparts.

### SUMMARY

Example embodiments of the inventive concept provide a simplified semiconductor fabrication method and a memory device fabricated thereby.

Other example embodiments of the inventive concept provide a highly integrated semiconductor device and a method of fabricating the same.

According to example embodiments of the inventive concept, a semiconductor memory device may include a vertical electrode on a substrate, a blocking insulating layer on a sidewall of the vertical electrode, a plurality of active patterns sequentially stacked on the substrate and spaced apart from the vertical electrode by the blocking insulating layer, and memory patterns between the active patterns.

In example embodiments, the memory patterns may include a charge storing layer, and the charge storing layer may be configured to store electric charges therein using fringe field generated from the vertical electrode.

In example embodiments, the memory patterns may further include a tunnel insulating layer between the charge storing layer and the active patterns.

In example embodiments, the tunnel insulating layer may include a first tunnel insulating layer under the charge storing layer and a second tunnel insulating layer on the charge storing layer.

In example embodiments, the blocking insulating layer may be thicker than the first tunnel insulating layer and the second tunnel insulating layer.

In example embodiments, the charge storing layer may be in contact with the blocking insulating layer.

In example embodiments, the blocking insulating layer may be extended in between the vertical electrode and the substrate.

In example embodiments, the vertical electrode may be provided in plural, and the semiconductor memory device may further include gap-filling patterns provided between the plurality of vertical electrodes.

In example embodiments, the plurality of vertical electrodes and the gap-filling patterns may be alternately disposed in a first direction parallel to a surface of the substrate, and the active patterns and the memory patterns extend along the first direction.

In example embodiments, sidewalls of the active patterns and the memory patterns may be in contact with the gap-filling patterns.

According to other example embodiments of the inventive concept, a semiconductor memory device may include at least one stack including active patterns and memory patterns alternately and repeatedly stacked on a substrate, vertical electrodes extending along a sidewall of the stack and in a direction perpendicular to a surface of the substrate, and a blocking insulating layer interposed between the stack and the vertical electrodes.

In example embodiments, each of the memory patterns may include a first tunnel insulating layer, a charge storing layer, and a second tunnel insulating layer stacked in a sequential manner.

In example embodiments, the memory patterns may have a sidewall in contact with the blocking insulating layer, and an extension direction of the memory pattern may be substantially perpendicular to that of the blocking insulating layer.

In example embodiments, the charge storing layer may be configured to store electric charges therein using fringe field generated from the vertical electrodes.

In example embodiments, the at least one stack may include a plurality of stacks spaced apart from each other with the vertical electrodes interposed therebetween.

In example embodiments, the vertical electrodes may be spaced apart from the substrate by the blocking insulating layer.

According to example embodiments of the inventive concept, a semiconductor memory device may include a first active pattern and a second active pattern adjacent to the first active pattern, a charge storing layer between the first active pattern and the second active pattern, a first tunnel insulating layer between the charge storing layer and the first active pattern, a second tunnel insulating layer between the charge storing layer and the second active pattern, a blocking insulating layer extending along sidewalls of the first and second active patterns, the first and second tunnel insulating layers, and the charge storing layer, and a gate electrode spaced apart from the charge storing layer with the blocking insulating layer interposed therebetween.

In example embodiments, the first and second tunnel insulating layers may be substantially perpendicular to the blocking insulating layer.

In example embodiments, the charge storing layer may be configured to store electric charges therein fringe field generated from the gate electrode.

According to still other example embodiments of the inventive concept, a method of fabricating a semiconductor memory device may include alternately and repeatedly forming active layers and memory layers on a substrate, forming trenches to penetrate the active layers and the memory layers, forming gap-filling patterns in the trenches to define through holes exposing a surface of the substrate, and sequentially forming a blocking insulating layer and a vertical electrode in the through holes.

In example embodiments, the forming of the memory layer may include sequentially forming a first tunnel insulating layer, a charge storing layer, a second tunnel insulating layer.

In example embodiments, the through holes may be formed to expose sidewalls of the active layers and the memory layers, and the blocking insulating layer may be formed to be in contact with the active layers and the memory layers.

In example embodiments, the blocking insulating layer may be formed thicker than the first tunnel insulating layer and the second tunnel insulating layer.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a circuit diagram illustrating a semiconductor memory device according to example embodiments of the inventive concept.

FIG. 2 is a perspective view of a semiconductor memory device according to example embodiments of the inventive concept.

FIG. 3 is a schematic sectional view illustrating a memory cell of a semiconductor memory device according to example embodiments of the inventive concept.

FIGS. 4 through 7 are perspective views illustrating a method of fabricating a semiconductor memory device, according to example embodiments of the inventive concept.

FIG. 8 is a schematic block diagram illustrating an example of a memory system including a semiconductor memory device according to example embodiments of the inventive concept.

FIG. 9 is a schematic block diagram illustrating an example of a memory card including a semiconductor memory device according to example embodiments of the inventive concept.

FIG. 10 is a schematic block diagram illustrating an example of an information processing system including a semiconductor memory device according to example embodiments of the inventive concept.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Example embodiments of the inventive concepts will now be described more fully with reference to the accompanying drawings, in which example embodiments are shown. Example embodiments of the inventive concepts may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Unless otherwise defined, all terms (including technical and scientific terms) used herein have the same meaning as commonly understood by one of ordinary skill in the art to which example embodiments of the inventive concepts belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

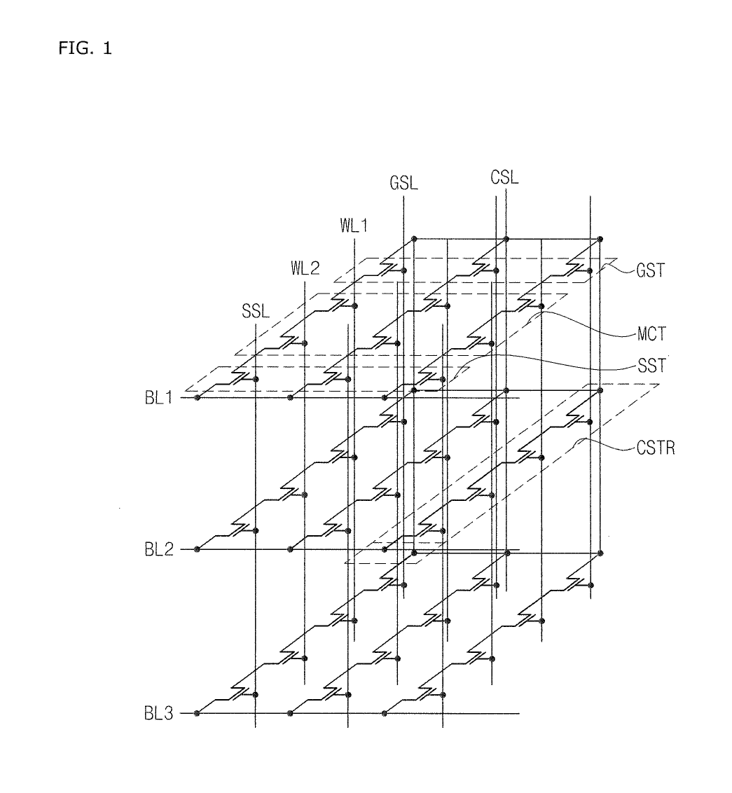

FIG. 1 is a circuit diagram illustrating a semiconductor memory device according to example embodiments of the inventive concept.

Referring to FIG. 1, a semiconductor memory device according to example embodiments of the inventive concept may include a common source line CSL, a plurality of bit lines BL1, BL2 and BL3, and a plurality of cell strings CSTR disposed between the common source line CSL and the bit lines BL1-BL3.

The common source line CSL may be a conductive layer disposed on a substrate (e.g., a semiconductor substrate) or an impurity region formed in the substrate. The bit lines BL1-BL3 may be conductive patterns (e.g., metal lines) disposed over the substrate and separated from the substrate. The plurality of cell strings CSTR may be connected to each of the bit lines BL1-BL3.

Each of the cell strings CSTR may be configured to include a ground selection transistor GST connected to the common source line CSL, a string selection transistor SST connected to one of the bit lines BL1-BL3, and a plurality of memory cell transistors MCT disposed between the ground selection transistor GST and the string selection transistor SST. The ground selection transistor GST, the memory cell transistors MCT, and the string selection transistor SST may be connected in series. Furthermore, a ground selection line GSL, a plurality of word lines WL1-WL2, and a string selection line SSL may be provided between the common source line CSL and the bit lines BL1-BL3 to serve as gate electrodes for the ground selection transistor GST, the memory cell transistors MCT, and the string selection transistors SST.

The ground and string selection transistors GST and SST and the memory cell transistors MCT may be a metal-oxide-semiconductor field effect transistor (MOSFET), in which a semiconductor layer is used as a channel region.

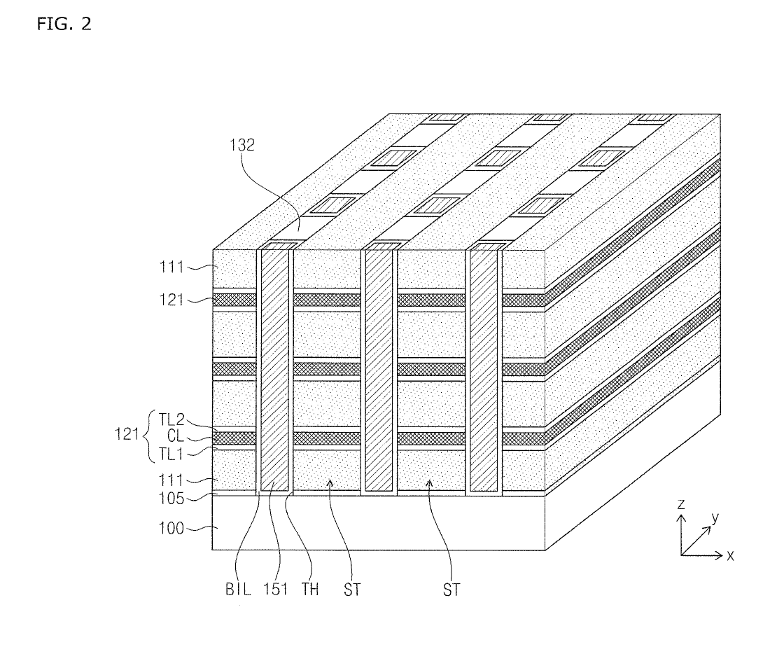

FIG. 2 is a perspective view of a semiconductor memory device according to example embodiments of the inventive concept.

Referring to FIG. 2, a substrate 100 may be provided. The substrate 100 may be a silicon wafer, a germanium wafer, or a silicon-germanium wafer. For example, the substrate 100 may be a wafer doped with p-type dopants. A plurality of stacks ST may be provided on the substrate 100. The stacks ST may include active patterns 111 and memory patterns 121 alternately and repeatedly stacked on the substrate 100. In the drawings, the active patterns 111 provided at four different levels and the memory patterns 121 provided on three different levels are illustrated in order to reduce complexity in the drawings and to provide better understanding of example embodiments of the inventive concept, but example embodiments of the inventive concept are not limited thereto. A buffer insulating layer 105 may be provided between the substrate 100 and the stacks ST. The buffer insulating layer 105 may be formed of or include a silicon oxide layer or a silicon oxynitride layer.

The active patterns 111 may include a semiconductor material, such as silicon, germanium, or the like. As an example, the active patterns 111 may be formed of or include a poly silicon layer. The active patterns 111 may be doped to have an n-type or a p-type. The memory patterns 121 may include a first tunnel insulating layer TL1, a second tunnel insulating layer TL2, and a charge storing layer CL between the first and second tunnel insulating layers TL1 and TL2.

Hereinafter, the memory patterns 121 will be described in more detail.

The charge storing layer CL may include one of insulating layers with many trap sites and insulating layers with nano particles and may be formed by one of a chemical vapor deposition (CVD) or an atomic layer deposition (ALD). For example, the charge storing layer CL may include one of a trap insulating layer, a floating gate electrode, or an insulating layer with conductive nano dots. As an example, the charge storing layer CL may include at least one of a silicon nitride layer, a silicon oxynitride layer, a silicon-rich nitride layer, a nanocrystalline silicon layer, or a laminated trap layer.

First and second tunnel insulating layers TL1 and TL2 may include a material, whose bandgap is greater than that of the charge storing layer CL, and may be formed by one of a chemical vapor deposition or an atomic layer deposition. For example, the first and second tunnel insulating layers TL1 and TL2 may be a silicon oxide layer, which may be formed using one of the above deposition techniques. As an example, a thermal treatment process may be performed on the first and second tunnel insulating layers TL1 and TL2. The thermal treatment process may be a rapid thermal nitridation (RTN) process or an annealing process to be performed under atmosphere containing at least one of nitrogen and oxygen. The first tunnel insulating layer TL1 may be formed of or include the same material as that of the second tunnel insulating layer TL2, but example embodiments of the inventive concept are not limited thereto and the first and second tunnel insulating layers TL1 and TL2 may be formed of or include different materials.

A blocking insulating layer BIL may be formed of or include a material having a band gap larger than that of the charge storing layer CL. The blocking insulating layer BIL may be a single layer or may include a plurality of layers. As an example, the blocking insulating layer BIL may include a first blocking insulating layer and a second blocking insulating layer. The first and second blocking insulating layers may be formed of different materials, and one of the first and second blocking insulating layers may have a band gap that is smaller than those of the first and second tunnel insulating layers TL1 and TL2 and larger than that of the charge storing layer CL. The first and second blocking insulating layers may be formed using one of a chemical vapor deposition or an atomic layer deposition, and at least one of them may be formed using a wet oxidation process. In example embodiments, the first blocking insulating layer may be formed of or include one of high-k dielectrics (e.g., aluminum oxide and hafnium oxide), and the second blocking insulating layer may be formed of or include a material whose dielectric constant is lower than that of the first blocking insulating layer. In other example embodiments, the second blocking insulating layer may be formed of or include one of the high-k dielectrics, and the first blocking insulating layer may be formed of or include a material whose dielectric constant is lower than that of the second blocking insulating layer.

The active patterns 111 and the memory patterns 121 may extend parallel to a y direction. Each of the stacks ST may include the active patterns 111 and the memory patterns 121 which are alternately stacked on the substrate 100 in a z direction, and an adjacent pair of the stacks ST may be spaced apart from each other in an x direction by the gap-filling patterns 132 and the vertical electrodes 151.

The vertical electrodes 151 may be provided in through holes TH between the stacks ST and may be spaced apart from the stacks ST by the blocking insulating layer BIL. In other words, the vertical electrodes 151 may extend along sidewalls of the stacks ST and the blocking insulating layer BIL may extend between the stacks ST and the vertical electrodes 151. The vertical electrodes 151 may be formed of or include at least one of metals, conductive metal nitrides, or doped semiconductor materials. As an example, the vertical electrodes 151 may include tungsten, titanium, or tantalum. The blocking insulating layer BIL may extend from the sidewalls of the vertical electrodes 151 in between a bottom surface of the vertical electrodes 151 and the substrate 100.

The gap-filling patterns 132 may be provided between the vertical electrodes 151 arranged in the y direction. As an example, the gap-filling patterns 132 may be formed of or include a silicon oxide layer or a silicon oxynitride layer. The vertical electrodes 151 and the gap-filling patterns 132 may be alternately disposed in a first direction (e.g., the y direction) parallel to a surface of the substrate 100, and the active patterns 111 and the memory patterns 121 may be elongated along the first direction. Sidewalls of the active and memory patterns 111 and 121 may be in contact with the gap-filling patterns 132.

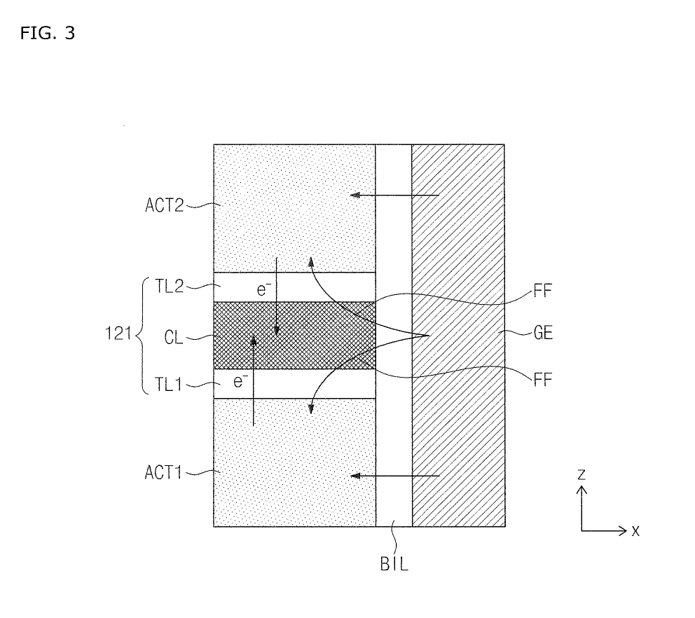

FIG. 3 is a schematic sectional view illustrating a memory cell of a semiconductor memory device according to example embodiments of the inventive concept.

The memory pattern 121 may be provided between a first active pattern

ACT1 and a second active pattern ACT2. The first and second active patterns ACT1 and ACT2 may correspond to the active patterns 111 of FIG. 2.

The memory pattern 121 may include the charge storing layer CL configured to store electric charges. The first tunnel insulating layer TL1 may be provided between the charge storing layer CL and the first active pattern ACT1, and the second tunnel insulating layer TL2 may be provided between the charge storing layer CL and the second active pattern ACT2.

The blocking insulating layer BIL may be provided to cover at least partially sidewalls of the first and second active patterns ACT1 and ACT2, the first and second tunnel insulating layers TL1 and TL2, and the charge storing layer CL. The first and second tunnel insulating layers TL1 and TL2 may be provided to be substantially perpendicular to vertical surfaces of the blocking insulating layer BIL. The blocking insulating layer BIL may be thicker than each of the first and second tunnel insulating layers TL1 and TL2. A gate electrode GE may be provided to be spaced apart from the charge storing layer CL with the blocking insulating layer BIL interposed therebetween. In example embodiments, the gate electrode GE may correspond to the vertical electrodes 151 of FIG. 2. The blocking insulating layer BIL may be in contact with the charge storing layer CL.

In the case where a program voltage is applied to the gate electrode GE, fringing field FF may be generated from the gate electrode GE and may be applied to the memory patterns 121 between the first and second active patterns ACT1 and ACT2. The fringing field FF may allow electric charges to be injected to the charge storing layer CL from the first and second active patterns ACT1 and ACT2. For example, due to the presence of the fringing field FF, a Fowler-Nordheim tunneling, allowing electric charges to be stored in the charge storing layer CL, may occur through at least one of the first and second tunnel insulating layers TL1 and TL2. The program voltage may be, for example, a negative voltage. Electric charges stored in the charge storing layer CL may lead to an increase in threshold voltage of the memory cell. In example embodiments, the charge storing layer CL may be configured to store data of one bit. However, in other example embodiments, in the case where voltages applied to an adjacent pair of the gate electrodes GE are controlled, it may be possible to store data of at least two bits in the charge storing layer CL.

According to example embodiments of the inventive concept, the fringing field may be used to perform a program operation on the memory cell. Furthermore, compared with the conventional 3D memory technologies, it is possible to more easily form the electrode patterns. In the case of the conventional 3D memory device, the gate electrodes are formed to extend in a horizontal direction, and semiconductor patterns serving as an active layer are formed to vertically penetrate the gate electrodes. Here, it is necessary to further provide a memory layer, along with the semiconductor pattern, in a contact hole, and this leads to an increase in size of the contact hole. As a result, the conventional 3D memory device suffers from a limitation in increasing an integration density thereof.

According to example embodiments of the inventive concept, the charge storing layer CL is not provided in the through holes TH, because it is provided to be parallel to a top surface of the substrate 100. This makes it possible to reduce a diameter or width of the through holes TH and consequently to increase an integration density of a memory device. In addition, since the electrodes are vertically formed with respect to the substrate 100, it is possible to more simplify an overall fabrication process, compared with the conventional 3D semiconductor technology.

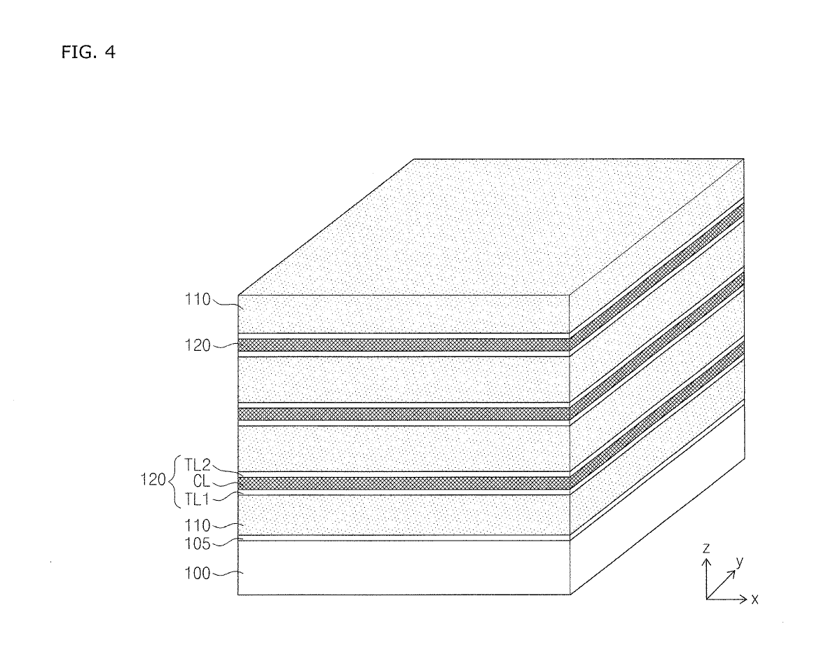

FIGS. 4 through 7 are perspective views illustrating a method of fabricating a semiconductor memory device, according to example embodiments of the inventive concept.

Referring to FIG. 4, the buffer insulating layer 105 may be formed on the substrate 100. The buffer insulating layer 105 may be formed of or include a silicon oxide layer or a silicon oxynitride layer. As an example, the buffer insulating layer 105 may be formed by a thermal oxidation process or a chemical vapor deposition (CVD) process. Active layers 110 and memory layers 120 may be alternately and repeatedly formed on the buffer insulating layer 105. The active layers 110 may include a semiconductor material, such as silicon, germanium, or the like. As an example, the active layers 110 may be formed of or include a poly silicon layer. The active layers 110 may be doped to have an n-type or a p-type.

The memory layers 120 may include the first tunnel insulating layer TL1, the second tunnel insulating layer TL2, and the charge storing layer CL between the first and second tunnel insulating layers TL1 and TL2. The charge storing layer CL may include one of insulating layers with many trap sites and insulating layers with nano particles. For example, the charge storing layer CL may include one of a trap insulating layer, a floating gate electrode, or an insulating layer with conductive nano dots. As an example, the charge storing layer CL may include at least one of a silicon nitride layer, a silicon oxynitride layer, a silicon-rich nitride layer, a nanocrystalline silicon layer, or a laminated trap layer.

The active layers 110 and the memory layers 120 may be formed by at least one of chemical vapor deposition (CVD), atomic layer deposition (ALD), or physical vapor deposition (PVD) processes.

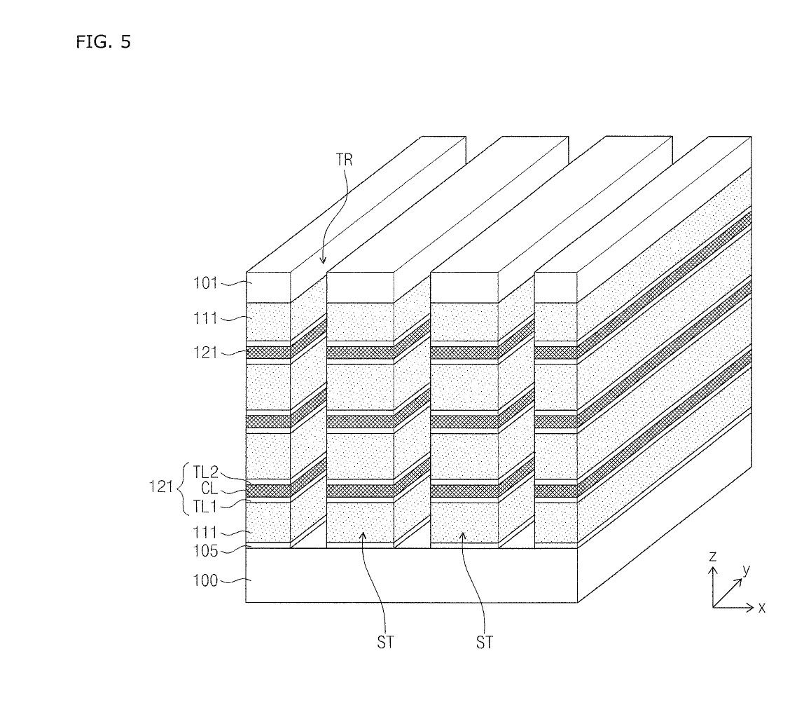

Referring to FIG. 5, a patterning process may be performed on the resulting structure provided on the substrate 100 to form trenches TR exposing the substrate 100. The formation of the trenches TR may include forming first mask patterns 101 on the uppermost one of the active layers 110 and performing an anisotropic etching process using the first mask patterns 101 as an etch mask. Each of the first mask patterns 101 may be a line shaped structure extending in the y direction. As a result, the stacks ST including the active patterns 111 and the memory patterns 121 may be formed to be spaced apart from each other by the trenches TR. The first mask patterns 101 may be removed after the etching process.

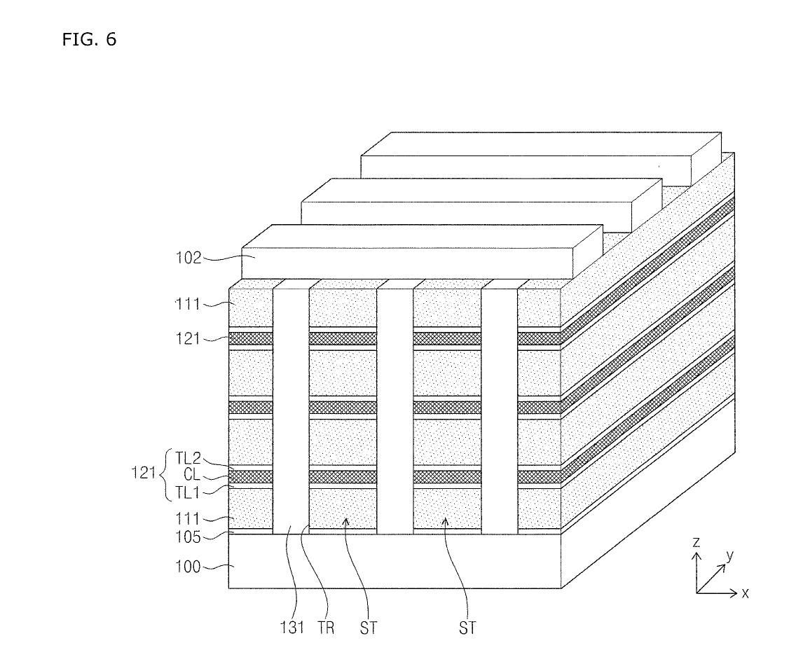

Referring to FIG. 6, a gap-filling layer 131 may be formed to fill the trenches TR. As an example, the gap-filling layer 131 may be formed of or include a silicon oxide layer or a silicon oxynitride layer. The gap-filling layer 131 may be formed by filling an insulating layer to fill the trenches TR and performing a planarization process thereon. The insulating layer may be formed using, for example, a CVD process.

Second mask patterns 102 may be formed on the structure provided with the gap-filling layer 131. The second mask patterns 102 may be formed of or include the same material as that of the first mask patterns 101. Each of the second mask patterns 102 may be a line-shape structure extending in the x direction crossing the first mask patterns 101.

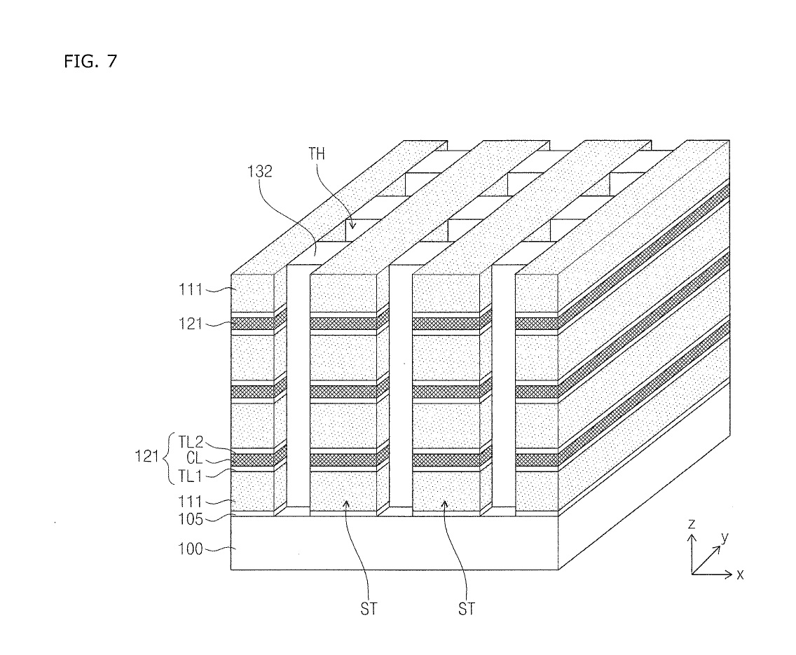

Referring to FIG. 7, the gap-filling layer 131 exposed by the second mask patterns 102 may be removed to form the gap-filling patterns 132. The gap-filling patterns 132 may be spaced apart from each other in the y direction by the through holes TH interposed therebetween. The through holes TH may be formed to expose the substrate 100, but example embodiments of the inventive concept are not limited thereto.

Referring back to FIG. 2, the blocking insulating layer BIL and the vertical electrodes 151 may be sequentially formed in the through holes TH. The formation of the blocking insulating layer BIL and the vertical electrodes 151 may include sequentially forming an insulating layer and a conductive layer on the structure provided with the through holes TH and performing a planarization process thereon. The blocking insulating layer BIL may be formed to be thicker than the first and second tunnel insulating layers TL1 and TL2. As an example, the insulating layer and the conductive layer may be formed by a CVD or sputtering process. The blocking insulating layer BIL may be extended in between the substrate 100 and the vertical electrodes 151.

According to example embodiments of the inventive concept, it is possible to fabricate a semiconductor memory device, in which fringing field is used to store electric charges in a charge storing layer. This makes it possible to increase an integration density of a three-dimensional memory device and more easily form gate electrodes for the memory device.

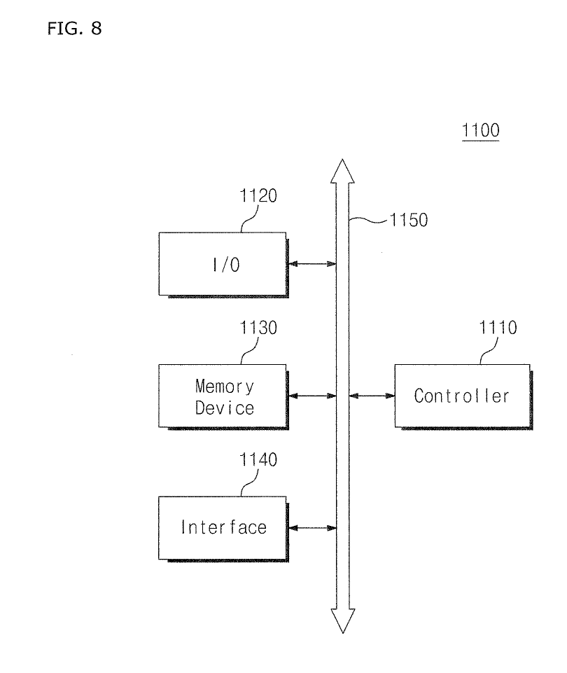

FIG. 8 is a schematic block diagram illustrating an example of a memory system including a semiconductor memory device according to example embodiments of the inventive concept.

Referring to FIG. 8, a memory system 1100 may be used to realize information processing devices, such as PDA, portable computers, web tablets, wireless phones, mobile phones, digital music players, memory cards, and wired or wireless communication devices.

The memory system 1100 may include a controller 1110, an input-output unit 1120 (e.g., a keypad, a keyboard, and a display), a memory 1130, an interface 1140, and a bus 1150. The memory 1130 and the interface 1140 may communicate with each other via the bus 1150.

The controller 1110 may include at least one of micro-processor, digital signal processor, a microcontroller, or other similar processing devices. The memory 1130 may be configured to store data or command processed by the controller 1110. The input-output unit 1120 may be configured to receive or output data or signals from or to the outside of the system 1100 or system 1100. For example, the input-output unit 1120 may include a keyboard, a keypad, or a display device.

The memory 1130 may include a semiconductor memory device according to example embodiments of the inventive concept. The memory 1130 may further include a randomly accessible volatile memory or any other type memory device.

The interface 1140 may be configured to receive or output data or signals from or to a communication network.

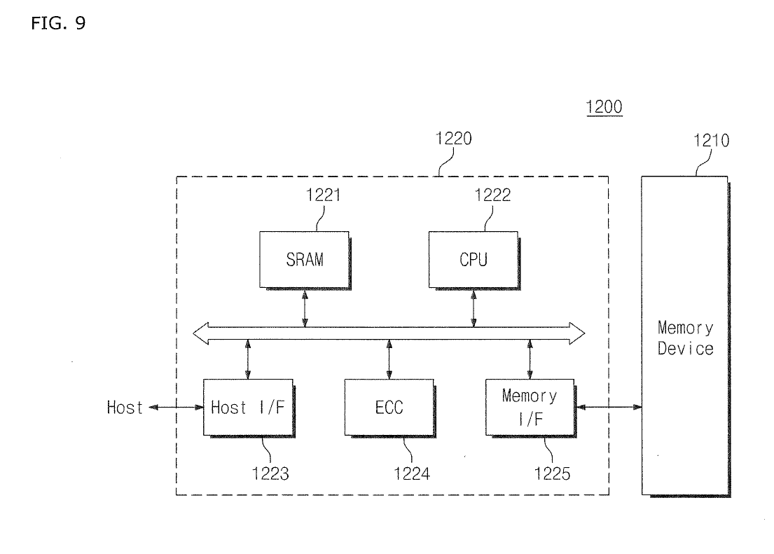

FIG. 9 is a schematic block diagram illustrating an example of a memory card including a semiconductor memory device according to example embodiments of the inventive concept.

Referring to FIG. 9, a memory card 1200 may be configured to include a semiconductor memory device 1210, which may be one of the semiconductor memory devices according to example embodiments of the inventive concept. The memory card 1200 includes a memory controller 1220 configured to control a data exchange operation between a host and the semiconductor memory device 1210.

A static random access memory (SRAM) 1221 may be used as an operation memory of a processing unit 1222. A host interface 1223 may be configured to include data exchange protocols of a host to be connected to the memory card 1200. An error correction block 1224 may be configured to detect and correct errors included in data readout from the semiconductor memory device 1210. A memory interface 1225 interfaces with the semiconductor memory device 1210. The processing unit 1222 performs every control operation for exchanging data of the memory controller 1220. Even though not depicted in drawings, it is apparent to one of ordinary skill in the art that the memory card 1200 according to example embodiments of the inventive concept may further include a ROM ((not shown)) storing code data for interfacing with the host.

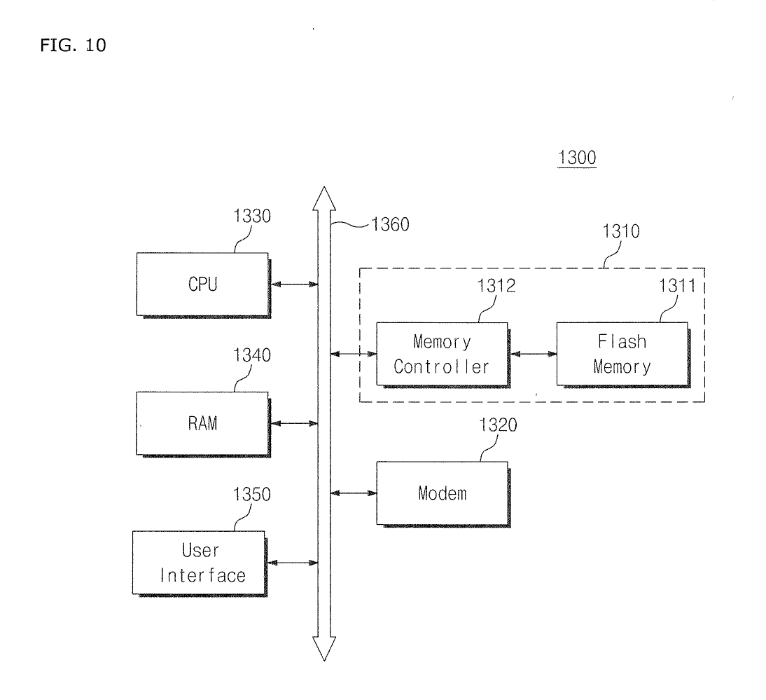

FIG. 10 is a schematic block diagram illustrating an example of an information processing system including a semiconductor memory device according to example embodiments of the inventive concept.

Referring to FIG. 10, an information processing system 1300, which may be a mobile device and/or a desktop computer, may include a memory system 1310 (e.g., a FLASH memory system). In example embodiments, the information processing system 1300 may further include a modem 1320, a central processing unit (CPU) 1330, a random access memory (RAM) 1340, and a user interface 1350 electrically connected to the memory system 1310 through a system bus 1360. The memory system 1310 may include a memory controller 1312 and a semiconductor memory device 1311, which may be one of the semiconductor memory devices according to example embodiments of the inventive concept. Data processed by the CPU 1330 and/or input from the outside may be stored in the memory system 1310. In some embodiments, the memory system 1310 may be used as a portion of a solid state drive (SSD), and in this case, the information processing system 1300 may stably and reliably store a large amount of data in the memory system 1310. This increase in reliability of the memory system 1310 enables the information processing system 1300 to conserve resources for error correction and realize a high speed data exchange function. Although not illustrated, it is apparent to those skilled in the art that, for example, an application chipset, a camera image sensor, a camera image signal processor (ISP), an input/output device, or the like may further be included in the information processing system 1300 according to the inventive concept.

Semiconductor memory devices or memory systems according to example embodiments of the inventive concept can be packaged using any of various types of packages. For example, a semiconductor memory device according to example embodiments of the inventive concept can be packaged with methods such as package on package (PoP), ball grid array (BGA), chip scale package (CSP), plastic leaded chip carrier (PLCC), plastic dual in-line package (PDIP), die in waffle pack, die in wafer form, chip on board (COB), ceramic dual in-line package (CERDIP), plastic metric quad flat pack (MQFP), thin quad flat pack (TQFP), small outline (SOIC), shrink small outline package (SSOP), thin small outline (TSOP), system in package (SIP), multichip package (MCP), wafer-level fabricated package (WFP), wafer-level processed stack package (WSP) and mounted.

According to example embodiments of the inventive concept, an electrode structure with insulating layers and metal silicide layers may be formed in an in-situ manner.

According to example embodiments of the inventive concept, a semiconductor memory device can be configured to have a high integration density.

While example embodiments of the inventive concepts have been particularly shown and described, it will be understood by one of ordinary skill in the art that variations in form and detail may be made therein without departing from the spirit and scope of the attached claims.

What is claimed is:

1. A semiconductor memory device, comprising:
a vertical electrode on a substrate;
a blocking insulating layer on a sidewall of the vertical electrode;
a plurality of active patterns sequentially stacked on the substrate and spaced apart from the vertical electrode by the blocking insulating layer; and
memory patterns between the active patterns.

2. The device of claim 1, wherein the memory patterns comprises a charge storing layer, and
the charge storing layer is configured to store electric charges therein using fringe field generated from the vertical electrode.

3. The device of claim 2, wherein the memory patterns further comprise a tunnel insulating layer between the charge storing layer and the active patterns.

4. The device of claim 3, wherein the tunnel insulating layer comprises a first tunnel insulating layer under the charge storing layer and a second tunnel insulating layer on the charge storing layer.

5. The device of claim 4, wherein the blocking insulating layer is thicker than the first tunnel insulating layer and the second tunnel insulating layer.

6. The device of claim 3, wherein the charge storing layer is in contact with the blocking insulating layer.

7. The device of claim 1, wherein the blocking insulating layer is extended in between the vertical electrode and the substrate.

8. The device of claim 1, wherein the vertical electrode is provided in plural, and the semiconductor memory device further comprises gap-filling patterns provided between the plurality of vertical electrodes.

9. The device of claim 8, wherein the plurality of vertical electrodes and the gap-filling patterns are alternately disposed in a first direction parallel to a surface of the substrate, and
the active patterns and the memory patterns extend along the first direction.

10. The device of claim 9, wherein sidewalls of the active patterns and the memory patterns are in contact with the gap-filling patterns.

11. A semiconductor memory device, comprising:
at least one stack including active patterns and memory patterns alternately and repeatedly stacked on a substrate;
vertical electrodes extending along a sidewall of the stack and in a direction perpendicular to a surface of the substrate; and
a blocking insulating layer interposed between the stack and the vertical electrodes.

12. The device of claim 11, wherein each of the memory patterns comprises a first tunnel insulating layer, a charge storing layer, and a second tunnel insulating layer stacked in a sequential manner.

13. The device of claim 12, wherein the memory patterns has a sidewall in contact with the blocking insulating layer, and
an extension direction of the memory pattern is substantially perpendicular to that of the blocking insulating layer.

14. The device of claim 12, wherein the charge storing layer is configured to store electric charges therein using fringe field generated from the vertical electrodes.

15. The device of claim 11, wherein the at least one stack comprises a plurality of stacks spaced apart from each other with the vertical electrodes interposed therebetween.

16. The device of claim 11, wherein the vertical electrodes are spaced apart from the substrate by the blocking insulating layer.

17. A semiconductor memory device, comprising:
a first active pattern and a second active pattern adjacent to the first active pattern;
a charge storing layer between the first active pattern and the second active pattern;
a first tunnel insulating layer between the charge storing layer and the first active pattern;
a second tunnel insulating layer between the charge storing layer and the second active pattern;
a blocking insulating layer extending along sidewalls of the first and second active patterns, sidewalls of the first and second tunnel insulating layers, and a sidewall of the charge storing layer; and
a gate electrode spaced apart from the charge storing layer by the blocking insulating layer interposed therebetween.

18. The device of claim 17, wherein the first and second tunnel insulating layers are substantially perpendicular to the blocking insulating layer.

19. The device of claim 17, wherein the charge storing layer is configured to store electric charges therein, using a fringe field generated from the gate electrode.

20. A method of fabricating a semiconductor memory device, comprising:
alternately and repeatedly forming active layers and memory layers on a substrate;
forming trenches to penetrate the active layers and the memory layers;
forming gap-filling patterns in the trenches to define through holes exposing a surface of the substrate; and
sequentially forming a blocking insulating layer and a vertical electrode in the through holes.

21. The method of claim 20, wherein the forming of the memory layer comprises sequentially forming a first tunnel insulating layer, a charge storing layer, a second tunnel insulating layer.

22. The method of claim 21, wherein the through holes are formed to expose sidewalls of the active layers and the memory layers, and the blocking insulating layer is formed to be in contact with the active layers and the memory layers.

23. The method of claim 21, wherein the blocking insulating layer is formed thicker than the first tunnel insulating layer and the second tunnel insulating layer.
